(19) United States
(12) Patent Application Publication
(10) Pub. No.: US 2013/0048078 A1
(43) Pub. Date: Feb. 28, 2013

(54) CARBON NANOTUBE-INVADED METAL OXIDE COMPOSITE FILM, MANUFACTURING METHOD THEREOF, AND ORGANIC SOLAR CELL WITH IMPROVED PHOTOELECTRIC CONVERSION EFFICIENCY AND IMPROVED DURATION USING SAME

(71) Applicants: Dong Chan Lim, Seoul (KR); Kyu Hwan Lee, Gyeongsangnam-do (KR); Yong Soo Jeong, Gyeongsangnam-do (KR); Won Hyun Shim, Gyeongsangbuk-do (KR); Sun Young Park, Gyeongsangnam-do (KR); Sung-Woo Cho, Daegu (KR)

(72) Inventors: Dong Chan Lim, Seoul (KR); Kyu Hwan Lee, Gyeongsangnam-do (KR); Yong Soo Jeong, Gyeongsangnam-do (KR); Won Hyun Shim, Gyeongsangbuk-do (KR); Sun Young Park, Gyeongsangnam-do (KR); Sung-Woo Cho, Daegu (KR)

(73) Assignee: KOREA INSTITUTE OF MACHINERY AND MATERIALS, Daejeon (KR)

(21) Appl. No.: 13/695,984

(22) PCT Filed: Dec. 22, 2010
(86) PCT No.: PCT/KR10/09218

§ 371 Date: Nov. 2, 2012

(30) Foreign Application Priority Data
May 20, 2010 (KR) 1020100047528
Dec. 22, 2010 (KR) 1020100132352

(51) Int. Cl. H01L 51/46; H01L 21/36; H01L 51/44; B32B 3/20; B82Y 40/00; B82Y 30/00

(52) U.S. Cl. 136/263; 428/220; 252/506; 252/507; 438/104; 977/784; 977/811; 977/842; 977/948; 257/E21.461

(57) ABSTRACT

The present invention relates to a carbon nanotube-invaded metal oxide composite film used as an N-type metal oxide conductive film of an organic solar cell, a manufacturing method thereof, and the organic solar cell with an improved photoelectric conversion efficiency and improved durability using the same, and more specifically, to a metal oxide-carbon nanotube composite film, a manufacturing method thereof, and an organic solar cell with an improved photoelectric conversion efficiency and improved durability using the same, characterized in that a single-wall carbon nanotube which has been surface-treated by a metal oxide is uniformly dispersed and is combined with the metal oxide.

### TECHNICAL FIELD

The present invention relates to a carbon nanotube-invaded metal oxide composite film, a manufacturing method thereof, and an organic solar cell with improved photoelectric conversion efficiency and improved durability using the same.

### BACKGROUND ART

Currently, organic photo-voltaic cell (OPV, see FIG. 12) is generally used and an inverse typed OPV (See FIG. 1) is also available. To improve photoelectric conversion efficiency of this organic solar cell, there is a method of increasing open circuit voltage (Voc) or short circuit current (Jsc) and new forms of photoactive organic materials have been researched to improve Voc. In order to increase Jsc, exciton generated from photoactive layer needs to be separated with ease, and the separated electrons and holes have to transfer quickly onto each electrode; therefore, a research that high-conductive nano-particles such as a new C₆₀ inducer or carbon nanotube are invaded inside of photoactive layer, or that the contact surface to photoactive layer is expanded by using metal or semi-conductor nano-wire to separate exiton and improve charge mobility, has been studied.

Meanwhile, there are mainly three methods to apply carbon nanotube to an organic solar cell. First method is applying carbon nanotube as a substitute material of transparent conductive substrate. That is, CNT electrode layer is formed directly on a glass or polymer substrate according to this method. Second method is invading inner photoactive layer by using carbon nanotube. Last method is applying carbon nanotube onto each layer in a thin and spider-web form. This method is developed to address the problems of deterioration of efficiency caused by each layer of an organic solar cell formed in layer-by-layer configuration which has increasing contact resistance of interface, and to improve conductibility. However, even if carbon nanotube is used inside of an organic material-photoactive layer, the relative efficiency of the carbon nanotube deteriorates compared to when C₆₀ inducer is used therein. Although the carbon nanotube forms a composite with organic materials, the efficiency change is variable depending on supply quantity. Also, since carbon nanotube is easily tangled and the length of carbon nanotube is in micro unit, if the carbon nanotube is applied for an organic solar cell according to the above-mentioned methods, the possibility of occurring short is increased.

Meanwhile, recently a research related to the durability of an organic solar cell has been studied as well as the improvement of photoelectric conversion efficiency. Since an organic solar cell is characterized based on its organic materials, the efficiency thereof directly deteriorates by moisture, oxygen and sun-light in air. So far, it has not clearly investigated the reasons causing efficiency deterioration of an organic solar cell, but many researchers have still been studying to investigate the reasons causing the same.

While researching a method of improving photoelectric conversion efficiency and durability of an organic solar cell, the inventors of the present invention dispersed carbon nanotube in metal oxide sol-gel solution with stability through simple solution process and developed a carbon nanotube-invaded metal oxide composite film, a manufacturing method thereof, and an organic solar cell with improved photoelectric conversion efficiency and durability using the same, and thus, completed the present invention.

### DISCLOSURE

### Technical Problem

The present invention aims to provide a carbon nanotube-invaded metal oxide composite film and a manufacturing method thereof by using a metal oxide solution in which carbon nanotube is dispersed with stability.

Also, the present invention aims to provide an organic solar cell with improved photoelectric conversion efficiency and durability using the carbon nanotube-invaded metal oxide composite film manufactured according to the above-mentioned method as N-type metal oxide conductive film of an organic solar cell.

### Technical Solution

In order to achieve the object explained above, the present invention provides a carbon nanotube-invaded metal oxide composite film in which single-wall carbon nanotube is uniformly dispersed in metal oxide.

Also, the present invention provides a method of manufacturing a carbon nanotube-invaded metal oxide composite film, the method comprising: preparing metal oxide sol-gel solution by sequentially dissolving metal oxide and stabilizer in ethanolic solution (step 1); adding and dispersing single-wall carbon nanotube in the metal oxide sol-gel solution prepared in step 1 to treat surface of single-wall carbon nanotube, and then performing centrifugation (step 2); adding and re-dispersing the surface treated single-wall carbon nanotube of step 2 in the metal oxide sol-gel solution prepared in step 1 (step 3); and coating transparent conductive electrode with the metal oxide sol-gel solution with dispersed single-wall carbon nanotube therein of step 3 and performing heat treatment (step 4).

Further, regarding an organic solar cell laminated in the order of substrate/transparent conductive electrode/N-type metal oxide conductive film/photoactive layer/P-type metal oxide conductive film/metal electrode, the present invention provides an organic solar cell having improved photoelectric conversion efficiency and durability, characterized in that the N-type conductive film thereof is the carbon nanotube-invaded metal oxide composite film.

### Advantageous Effects

Carbon nanotube-invaded metal oxide composite film according to the present invention improves mobility balance and speed of the entire electrons and holes as improving mobility of electrons generated from photoactive layer with single-wall carbon nanotube. Also, the carbon nanotube-invaded metal oxide composite film improves photoabsorption efficiency as amplifying the amount of solar energy absorbed in photoactive layer. A method of manufacturing carbon nanotube-invaded metal oxide composite film according to the present invention can maintain stable dispersion of carbon nanotube by simple solution process, and can use a variety of processes such as spin coating, spray coating or doctor-blading. Further, since photoelectric conversion efficiency of an organic solar cell having the carbon nanotube-invaded metal oxide composite film is improved and durability thereof is also improved by enhancing ultraviolet shielding effect due to the influence of the carbon nanotube, the organic solar cell can be a useful organic solar cell which provides low cost, high efficiency and long durability.

### BRIEF DESCRIPTIONS OF DRAWINGS

FIG. 1 presents a mimetic diagram illustrating an inverse-typed conventional OPV;

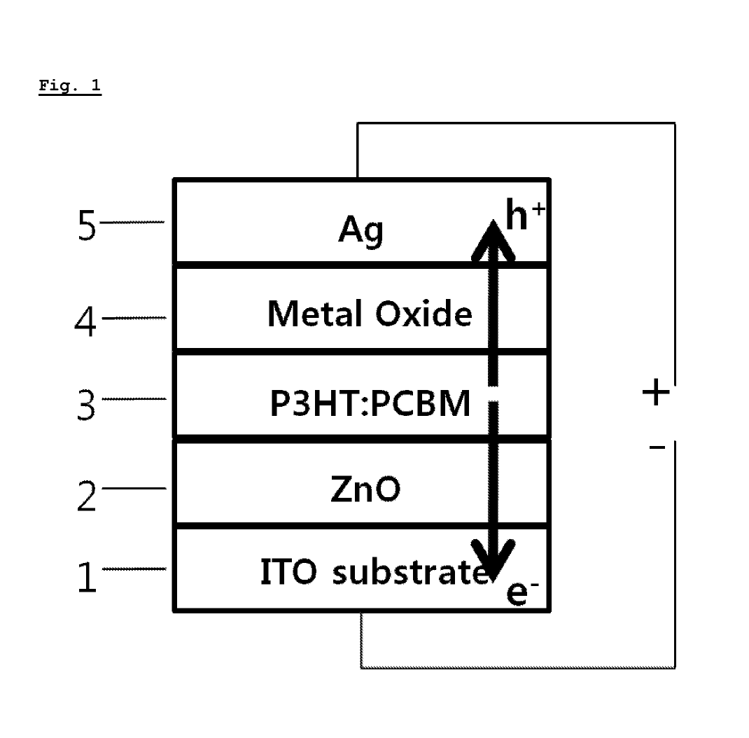

FIG. 2 presents a mimetic diagram illustrating an organic solar cell according to the present invention;

FIG. 3 presents a mimetic diagram illustrating single-wall carbon nanotube-invaded metal oxide;

FIG. 4 presents images of a zinc oxide sol-gel solution (A), a zinc oxide solution including single-wall carbon nanotube (B) and a zinc oxide solution including surface treated single-wall carbon nanotube;

FIG. 5 presents AFM (atomic force microscopy) images of carbon nanotube-invaded metal oxide composite film according to the present invention;

FIG. 6 presents a graph representing transmission rate of carbon nanotube-invaded metal oxide composite film according to the present invention;

FIG. 7 presents a graph representing photoelectric conversion efficiency of an organic solar cell according to the present invention;

FIG. 8 presents a graph representing mobility of electrons and holes of an organic solar cell according to the present invention;

FIG. 9 presents a graph representing photoluminescence (PL) intensity of an organic solar cell according to the present invention;

FIG. 10 presents graphs representing photoelectric conversion efficiency (Jsc) in the atmosphere regarding an organic solar cell according to the present invention;

FIG. 11 presents graphs representing photoelectric conversion efficiency (PCE) in the atmosphere regarding an organic solar cell according to the present invention;

FIG. 12 presents a graph representing photoelectric conversion efficiency in the atmosphere regarding a conventional OPV;

FIG. 13 presents a graph representing photoelectric conversion efficiency under ultra-violet light regarding an organic solar cell according to the present invention; and

FIG. 14 presents a TEM image illustrating carbon nanotube-invaded metal oxide composite film of an organic solar cell according to the present invention.

### EACH OF SYMBOLS FOR FIGS

1: Transparent conductive electrode
2: N-type metal oxide conductive film
3: Photoactive layer
4: P-type metal oxide conductive film
5: Metal electrode
6: Carbon nanotube-invaded metal oxide composite film
7: Single-wall carbon nanotube
8: Metal oxide

### BEST MODE

The present invention provides carbon nanotube-invaded metal oxide composite film in which single-wall carbon nanotube is uniformly dispersed in metal oxide.

In a carbon nanotube-invaded metal oxide composite film according to the present invention, the metal oxide may include: one type of N-type metal oxide selected from a group consisting of TiO₂, ZnO and SnO; a compound of two or more of the above; and the metal oxide doped with one or more kinds of atoms selected from a group consisting of Al, Ga, Ng, In and Sn. Thickness of the carbon nanotube-invaded metal oxide composite film may preferably be 10-100 nm. If thickness of the carbon nanotube-invaded metal oxide composite film is under 10 nm, N-type conductive film becomes too thin in an organic solar cell, so that the characteristics of interface for transparent conductive electrode deteriorates. Also, since the possibility to desorb carbon nanotube from carbon nanotube-invaded metal oxide composite film is increased, the metal oxide composite film cannot work as a conductive film. If thickness of the carbon nanotube-invaded metal oxide composite film exceeds 100 nm, since the electron-transfer distance becomes longer, the problem of deterioration of photoelectric conversion efficiency appears.

In addition, the present invention provides a method of manufacturing carbon nanotube-invaded metal oxide composite film, the method including steps of: preparing metal oxide sol-gel solution by sequentially dissolving metal oxide and stabilizer in ethanolic solution (step 1); adding and dispersing single-wall carbon nanotube in the metal oxide sol-gel solution prepared in step 1 to treat surface of single-wall carbon nanotube, and then performing centrifugation (step 2); adding and re-dispersing the surface treated single-wall carbon nanotube of step 2 in the metal oxide sol-gel solution prepared in step 1 (step 3); and coating transparent conductive electrode with the metal oxide sol-gel solution with dispersed single-wall carbon nanotube therein of step 3 and performing heat treatment (step 4).

Hereinafter, the present invention will be explained in greater detail.

According to a method of manufacturing carbon nanotube-invaded metal oxide composite film of the present invention, step 1 includes preparing sol-gel solution by sequentially dissolving metal oxide and stabilizer in ethaolic solution.

The metal oxide of step 1 may use: one type of N-type metal oxide selected from a group consisting of TiO₂, ZnO and SnO; a compound of two or more of the above; and the metal oxide doped with one or more kinds of atoms selected from a group consisting of Al, Ga, Ng, In and Sn. Also, the ethanolic solution of step 1 may include methoxyethanol or butoxyethanol, and ethanolamine may be used as stabilizer.

Further, the metal oxide content of step 1 is preferably between 0.1-1 M and the stabilizer content is preferably dissolved depending on the metal oxide content. More preferably, the stabilizer content is between 0.1-1 M. If metal oxide content is less than 0.1 M, the metal oxide content is not enough to form a metal oxide thin film with uniformly dispersed metal oxide. If metal oxide content exceeds 1 M, since the metal ratio becomes too high, it takes long period of time to be dispersed in a solution with stability and the metal oxide thin film with uniformly dispersed metal oxide cannot be formed.

Further, the metal oxide sol-gel solution of step 1 is manufactured preferably at 50-70° C. for 50-70 min. If temperature or time is below 50° C. or 50 min, the powder including metal oxide is not dissolved in a solution and if the temperature or the time exceeds 70° C. or 70 min, a problem related to aging of metal oxide appears.

According to a method of manufacturing carbon nanotube-invaded metal oxide composite film of the present invention, step 2 includes adding and dispersing single-wall carbon nanotube in the metal oxide sol-gel solution prepared in step 1 to treat the surface of single-wall carbon nanotube, and then performing centrifugation.

0.1-5 weight % of the single-wall carbon nanotube in step 2 is preferably added in metal oxide sol-gel solution. If the single-wall carbon nanotube is less than 0.1 weight %, less amount of carbon nanotube penetrates into metal oxide, so does not influence photoelectric conversion efficiency thereof or causes deterioration of photoelectric conversion efficiency. If the single-wall carbon nanotube exceeds 5 weight %, since excessive carbon nanotube content is applied, the nanotube is tangled and transmission rate is decreased when thin film is formed.

The dispersion of step 2 may preferably be performed for 50-70 min by using ultrasonic dispersion device, but not limited thereto.

If the metal oxide sol-gel solution of step 2 before centrifugation is placed at room temperature for a while, carbon nanotube on which the surface is treated with metal oxide is precipitated. In order to separate the surface treated carbon nanotube from the metal oxide sol-gel solution, centrifugation is preferably performed. This centrifugation may preferably be performed at 14,000-16,000 rpm, but not limited thereto.

According to a method of manufacturing carbon nanotube-invaded metal oxide composite film of the present invention, step 3 includes adding and re-dispersing the surface treated single-wall carbon nanotube of step 2 in the metal oxide sol-gel solution prepared in step 1.

The re-dispersion of step 3 is preferably performed by using ultrasonic wave to disperse the surface treated single-wall carbon nanotube into the metal oxide sol-gel solution; those are difficult to be dispersed. Through this re-dispersion process, the surface treated single-wall carbon nanotube can be dispersed with stability in metal oxide sol-gel solution even over the course of time without creating precipitates.

According to a method of manufacturing carbon nanotube-invaded metal oxide composite film of the present invention, step 4 includes coating transparent conductive electrode with the metal oxide sol-gel solution with re-dispersed single-wall carbon nanotube of step 3, and performing heat treatment.

The deposition process of step 4 may be performed by spin coating, spray coating or doctor-blading. Through this process, the carbon nanotube-invaded metal oxide composite film is deposited to 10-100 nm of thickness; therefore, the metal oxide composite film in which single-wall nanotube is uniformly dispersed and combined with metal oxide can be manufactured.

Also, the heat treatment of step 4 is preferably performed at 150-300° C. for 10-30 min on a hot plate. If the temperature or the time is under 150° C. or 10 min, the residues of metal oxide sol-gel solution appear on the surface of the composite film and metal oxide is not fully formed in the metal oxide sol-gel solution. If the temperature or the time exceeds 300° C. or 30 min, the grain size of thin film becomes large, so that the problem related to deterioration of electric or optical characteristics of the film is occurred.

Further, the present invention provides an organic solar cell including the carbon nanotube-invaded metal oxide composite film.

More specifically, regarding an organic solar cell laminated in the order of a substrate/transparent conductive electrode/N-type metal oxide/photoactive layer/P-type metal oxide conductive film/metal electrode, the present invention provides an organic solar cell with improved photoelectric conversion efficiency and durability, characterized in that the N-type metal oxide conductive film thereof is the carbon nanotube-invaded metal oxide.

Referring to Examples 3, 6 and 7, an organic solar cell according to the present invention uses carbon nanotube-invaded metal oxide composite film, and thus, photoelectric conversion efficiency and durability of the organic solar cell are improved from the conventional OPV.

Accordingly, carbon nanotube-invaded metal oxide composite film according to the present invention improves mobility balance and speed of the entire electrons and holes as improving mobility of electrons generated in photoactive layer with single-wall carbon nanotube. Also, the carbon nanotube-invaded metal oxide composite film improves photoabsorption efficiency as amplifying the amount of solar energy absorbed in photoactive layer. A method of manufacturing carbon nanotube-invaded metal oxide composite film according to the present invention can maintain stable dispersion of carbon nanotube by simple solution process, and can use a variety of processes such as spin coating, spray coating or doctor-blading. Further, since photoelectric conversion efficiency of an organic solar cell having the carbon nanotube-invaded metal oxide composite film is improved and durability thereof is also improved by ultraviolet shielding effect enhancement due to the influence of the carbon nanotube, a useful organic solar cell of low cost, high efficiency and long durability can be provided.

### MODE FOR INVENTION

The following is provided to explain the details of the present invention with examples and experimental examples, wherein, the present invention is only illustrated by the examples, thus, the present invention is not limited as the examples.

### Example 1

### A Method of Manufacturing Carbon Nanotube-Invaded Metal Oxide Composite Film

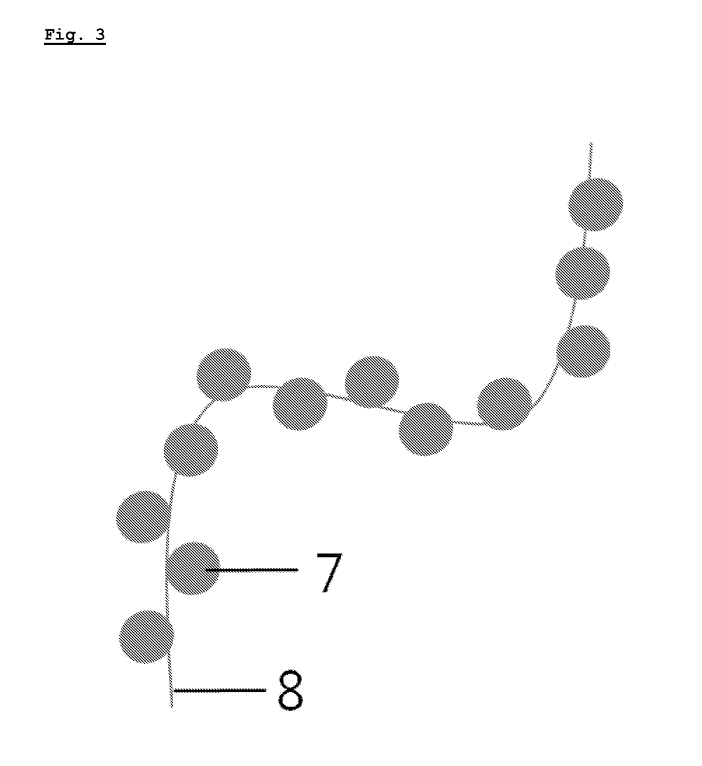

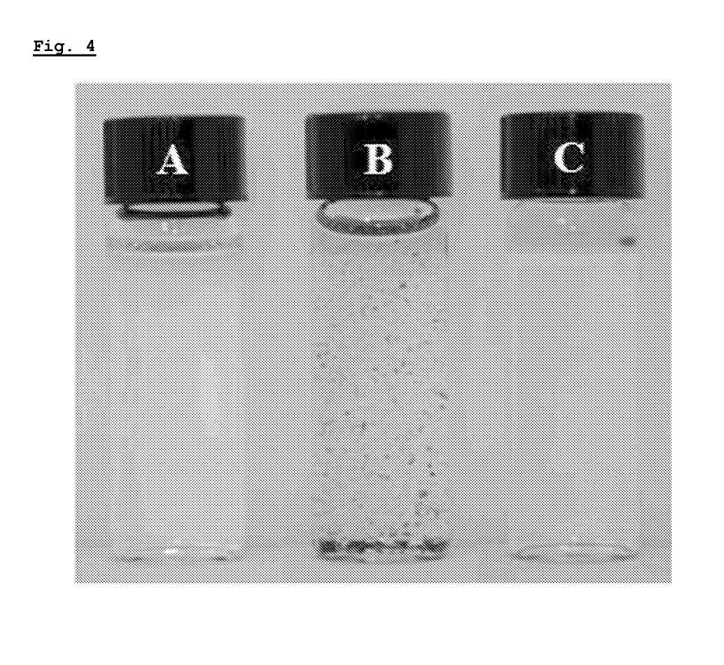

0.1-1 M of zinc acetate was dissolved in methoxyethanol or butoxyethanol with magnetic stick, and 0.1-1 M of ethanolamine was added therein as a stabilizer and dissolved on 60° C. hot plate for 1 hr to prepare zinc oxide (ZnO) sol-gel solution (See FIG. 4(A)). 0.1-5 weignt % of single-wall carbon nanotube having 100-1,000 nm length (Carbon solution Inc., P3-SWNT) was added in the prepared ZnO sol-gel solution and dispersed for 1 hr with ultrasonic dispersion device, then the solution was centrifuged at 15,000 rpm to filter out the surface treated single-wall carbon nanotube (See FIG. 3). Referring to FIG. 4 (B), before the ZnO sol-gel solution dispersed single-wall carbon nanotube centrifuged, the solution was placed at room temperature for 1 hr and the surface treated single-wall carbon nanotube was precipitated naturally. The surface treated single-wall carbon nanotube was added to the ZnO sol-gel solution prepared according to the above-explained method and re-dispersed by using ultrasonic wave (See FIG. 4 (C)). Then, the carbon nanotube was deposited on transparent conductive electrode (ITO) by spin coating or spray coating and heating process was performed on 150-300° C. hot plate for 10-30 min in the atmosphere to prepare carbon nanotube-invaded metal oxide composite film with a thickness of 10-100 nm.

### Example 2

### Method (I) of Manufacturing an Organic Solar Cell Including Carbon Nanotube-Invaded Metal Oxide Composite Film

1. Manufacture of Photoactive Layer

P3HT and PCBM were dispersed in a solvent (i.e., DCB:DB=1:0.6) at a ratio of 1:0.7, respectively and by spin coating, spray coating, dip coating or doctor blading, the dispersed P3HT:PCBM solution was deposited on the carbon nanotube-invaded metal oxide composite film prepared in Example 1. Then, the composite film was dried for 2 hrs at room temperature or treated with heat on hot plate for 10 min to prepare photoactive layer in a thickness of 100-400 nm.

2. Manufacture of P-Type Conductive Film

NiO metal oxide nano-particles were dispersed in IPA, DMF or DMSO solution and deposited on the photoactive layer by spin coating, spray coating, dip coating or doctor blading. Then, heat treatment was performed on 150° C. hot plate for 10 min to prepare NiO conductive film having 10-50 nm thickness.

3. Manufacture of Metal Electrode

Ag electrode was prepared on the P-type conductive layer with evaporator to have 100-150 nm of thickness.

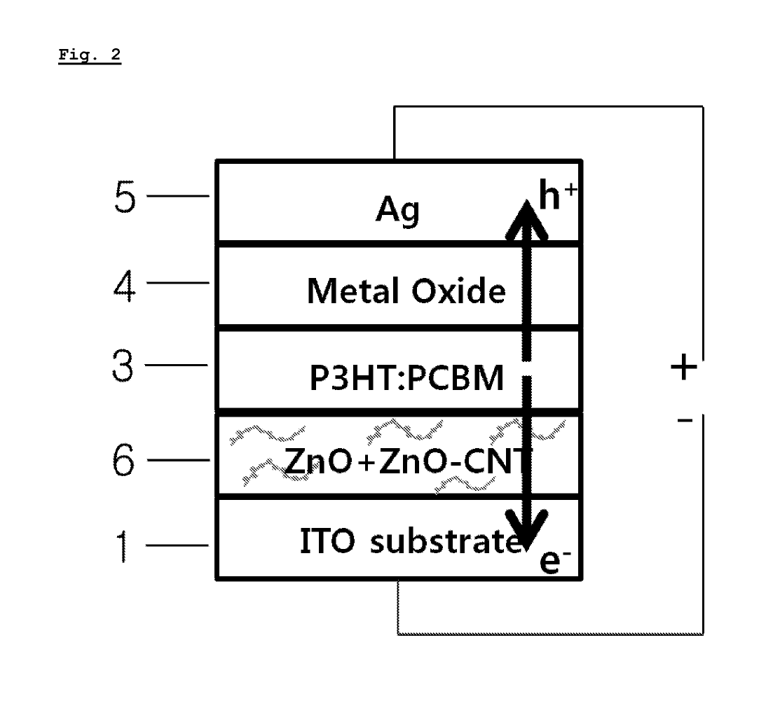

An organic solar cell prepared according to the above-mentioned method was treated with heat on 150° C. hot plate for 5 min (See FIG. 2).

### Example 3

### Method (II) of Manufacturing an Organic Solar Cell Including Carbon Nanotube-Invaded Metal Oxide Composite Film

In Example 3, n-heptane was used as a stabilizer; 1 weight % of carbon nanotube was added; and the carbon nanotube-invaded metal oxide composite film manufactured according to the identical method of Example 1, was used. Except for these, the rest processes of manufacturing an organic solar cell including carbon nanotube-invaded metal oxide composite film were identical to those according to the method of step 2.

### Comparative Example 1

### A Method of Manufacturing ZnO Metal Oxide Film

0.1-1 M of zinc acetate was dissolved in methoxyethanol or butoxyethanol with magnetic stick and 0.1-1 M of ethanolamine was added as a stabilizer and dissolved with 60° C. hot plate for 1 hr to prepare ZnO sol-gel solution. The prepared ZnO sol-gel solution was deposited on transparent conductive electrode (ITO) by spin coating or spray coating, and then heat-treated on 150-300° C. hot plate for 10-30 min in the atmosphere to prepare ZnO metal oxide film in a thickness of 10-100 nm.

### Comparative Example 2

### A Method of Manufacturing an Organic Solar Cell Including ZnO Metal Oxide Film

Except that the object on which manufactured photoactive layer is the ZnO metal oxide manufactured in Comparative Example 1, the rest processes of manufacturing an organic solar cell including ZnO metal oxide were identical to those according to the method of Example 2.

### Experimental Example 1

### Surface Analysis of Carbon Nanotube-Invaded Metal Oxide Composite Film

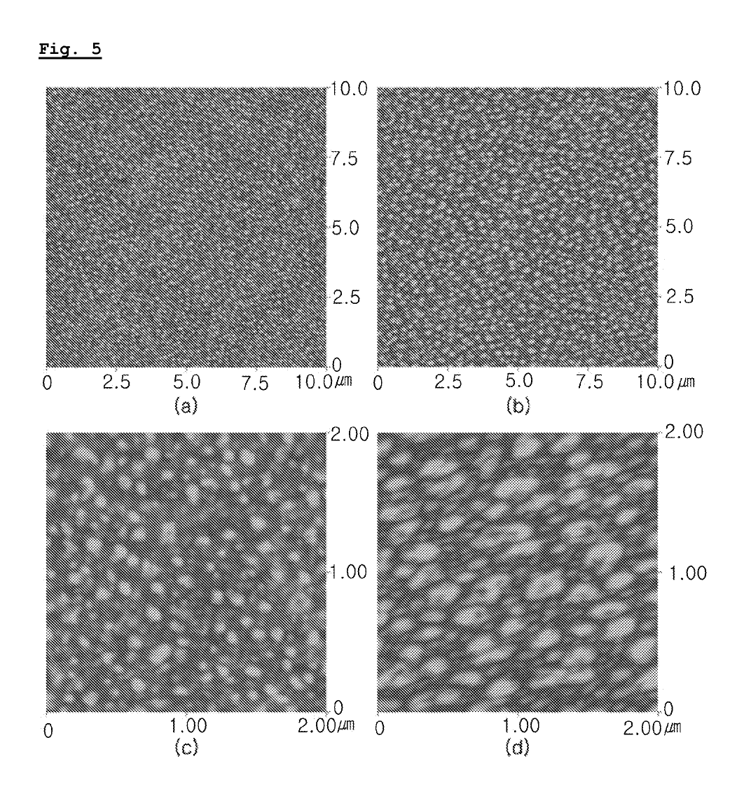

The surface of carbon nanotube-invaded metal oxide composite film according to the present invention was analyzed with AFM (Vecco, MMAFM-2) and the result is presented in FIG. 5.

Referring to FIG. 5, the thin film of Example 1 (FIG. 5 (b),(d)) has relatively rough surface and Comparative Example 1 (FIG. 5 (a), (c)) and Example 1 showed 4.23 nm and 8.86 nm of each rms (i.e., root mean square) value, a standard deviation presenting surface roughness. Accordingly, it was confirmed that the surface of carbon nanotube-invaded ZnO thin film presented approximately two times greater roughness than that of Comparative Example 1.

### Experimental Example 2

### Transmission Rate Analysis of Carbon Nanotube-Invaded Metal Oxide Composite Film

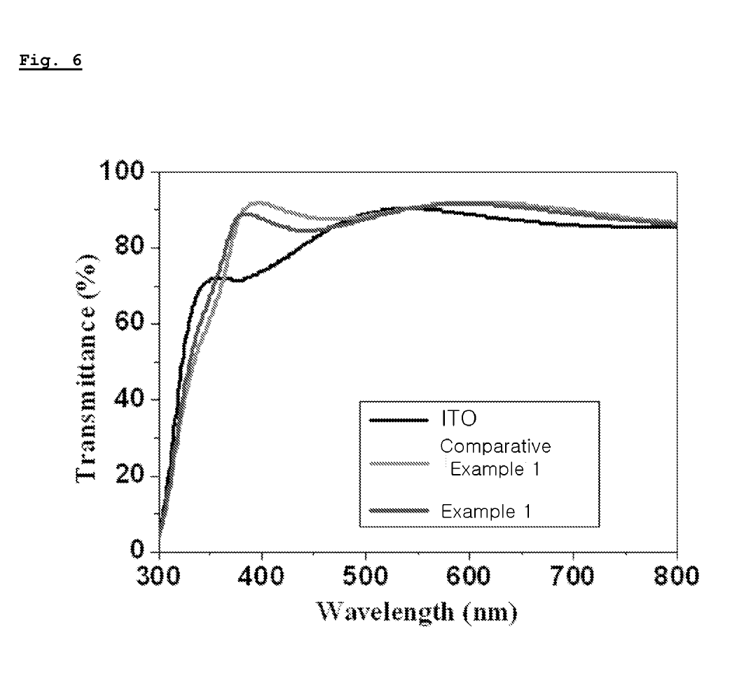

The transmission rate of the carbon nanotube-invaded metal oxide composite film according to the present invention was analyzed and the result is presented in FIG. 6.

Short circuit current value (Jsc) is co-related to transmission rate of the film, so that if the transmission rate of the transparent electrode is decreased, the amount of absorbable light related thereto is reduced; therefore, Jsc value is decreased. However, referring to FIG. 6, it was recognized that the composite film of Example 1 did not show decrease of transmission rate in visible wavelength region.

### Experimental Example 3

### Photo-Electric Conversion Efficiency Analysis of an Organic Solar Cell Including Carbon Nanotube-Invaded Metal Oxide Composite Film

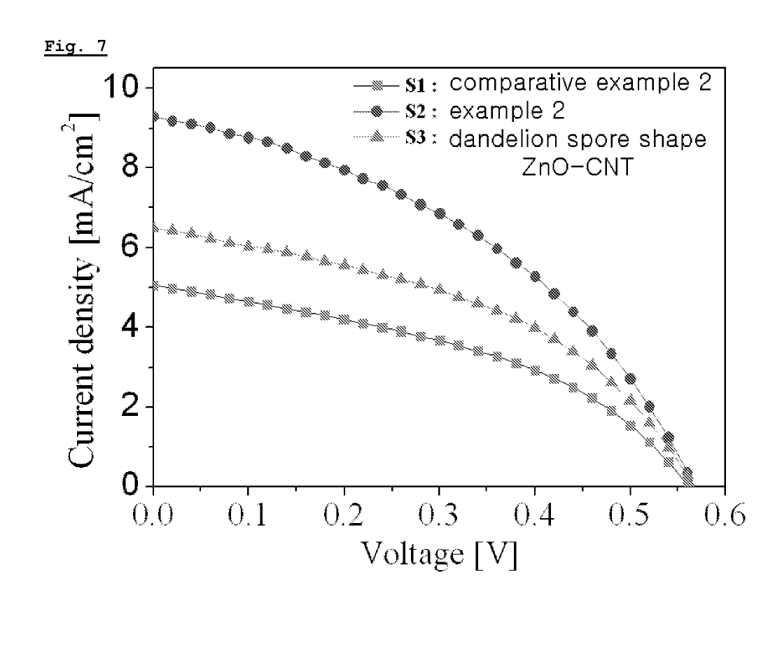

An optical solar simulator was used to measure photoelectric conversion efficiency of an organic solar cell including carbon nanotube-invaded metal oxide composite film, and the result is presented in FIG. 7 and Table 1.

The effective area of the cell was 0.38 cm² and an optical solar simulator under AM 1.5, 1 sun condition was used to measure photoelectric efficiency. Also, photoelectric conversion efficiency, curvature factor, open circuit voltage and short circuit current were measured, and then, the result is presented in FIG. 7 and Table 1.

TABLE 1

| | Photoelectric | | Open | Short |
|---|---|---|---|---|
| | Conversion | Curvature | Circuit | Circuit |
| Example | Efficiency | Factor | Voltage | Current |
| Comparative | 1.173 | 0.414 | 0.562 | 5.048 |
| Example 2 | | | | |
| Example 2 | 2.149 | 0.408 | 0.567 | 9.287 |
| Example 3 | 1.605 | 0.436 | 0.567 | 6.485 |

Referring to FIG. 7 and Table 1, it was recognized that organic solar cells of Examples 2 and 3 had higher photoelectric conversion efficiency than that of Comparative Example 2. That is, short circuit current (Jsc) value is remarkably increased. Referring to Experimental Example 1, due to the surface roughness, the short circuit current value was increased remarkably while photoelectric conversion efficiency deteriorated.

### Experimental Example 4

### Mobility Analysis Method of Electrons and Holes Regarding Carbon Nanotube-Invaded Metal Oxide Composite Film

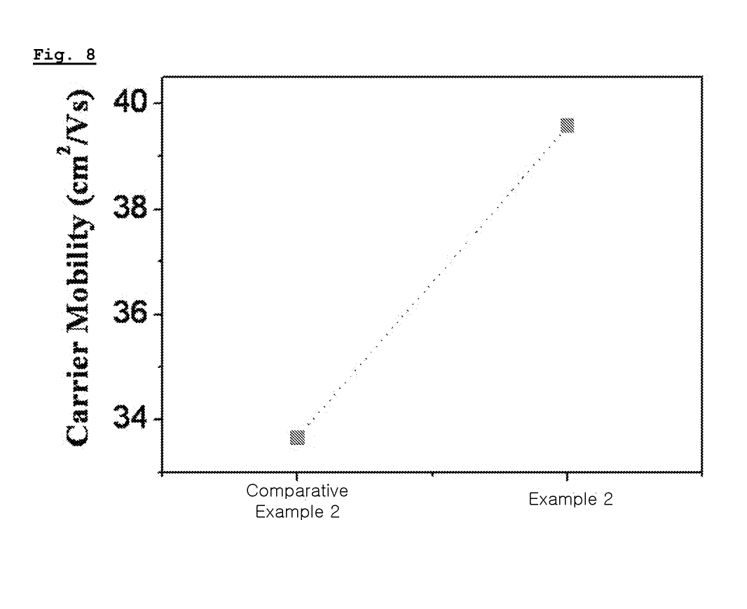

Mobility of electrons and holes regarding carbon nanotube-invaded metal oxide composite film according to the present invention was measured and the result is presented in FIG. 8.

Referring to FIG. 8, it was recognized that an organic solar cell of Example 2 had higher carrier mobility than a conventional OPV of Comparative Example 2.

### Experimental Example 5

### Photoluminescence Characteristics Analysis of an Organic Solar Cell

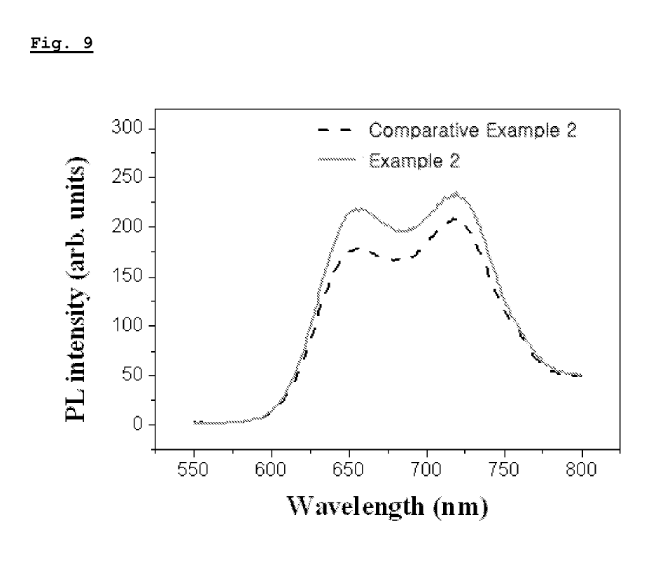

Photoluminescence (Hitachi, F-4500 FL) characteristics of an organic solar cell including carbon nanotube-invaded metal oxide composite film according to the present invention were analyzed and the result is presented in FIG. 9.

Referring to FIG. 9, it was recognized that an organic solar cell of Example 2 in which carbon nanotube-invaded metal oxide composite film was included, had higher photoluminescence characteristics than an organic solar cell of Comparative Example 2. Accordingly, although both organic solar cells show identical transmission, the higher photoluminescence characteristics causes light absorption rate to be increased and the value of short circuit current is increased.

### Experimental Example 6

### Photo-Electric Conversion Efficiency Analysis of an Organic Solar Cell in the Atmosphere

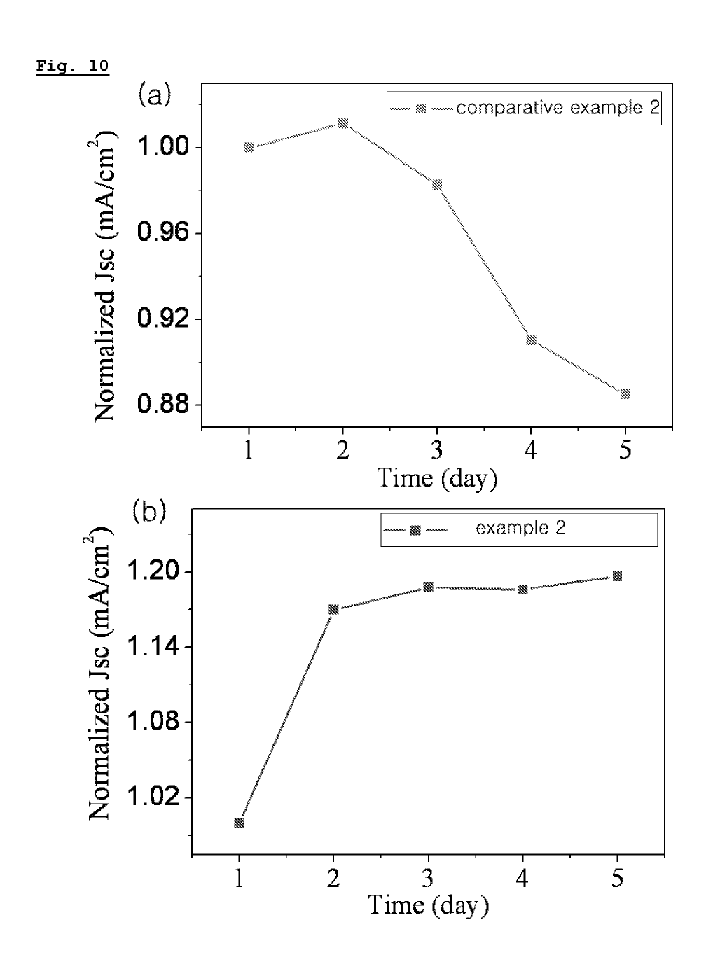

Photoelectric conversion efficiency of an organic solar cell according to the present invention was measured in the atmosphere, and the result is presented in FIGS. 10, 11, and 12.

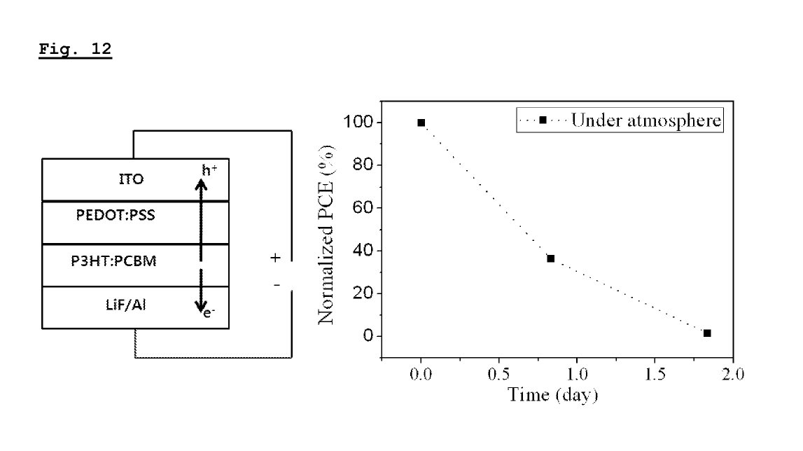

Referring to FIG. 12, it was recognized that since a conversion OPV of Comparative Example 2 had weak interface characteristics between the used materials, the interface was easily oxidized by oxygen or hydrogen and photoelectric conversion efficiency deteriorates rapidly. In contrast, an organic solar cell of Example 2 according to the present invention used N-type and P-type oxide semi-conductor in stable condition and Ag electrode was used instead of Al electrode, so that resistance against oxidation was relatively higher than that of Comparative Example 2.

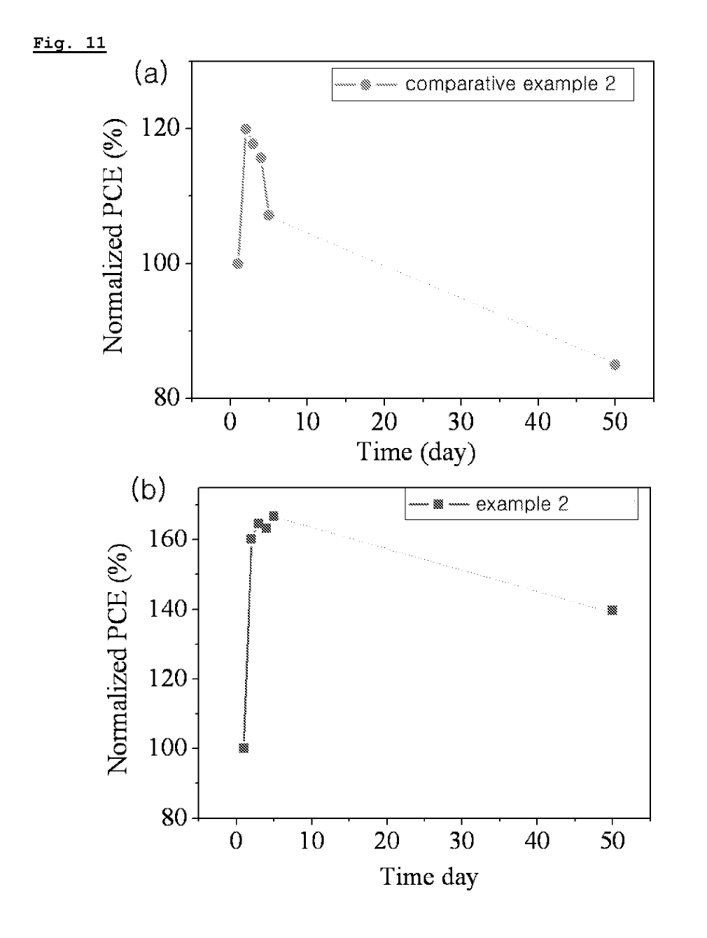

Also, referring to FIGS. 10 and 11, photoelectric conversion efficiency was gradually improved approximately for 3 days (See FIG. 10 (a), (b)) since wetting of each interface and crystalline of layer consisting organic materials were improved. That is, the wetting between carbon nanotube-invaded metal oxide composite film according to the present invention and photoactive layer, which presents the roughness of the surface, takes long time for well performance, so that photoelectric conversion efficiency thereof is gradually improved and it takes long period of time. The major reason for this improvement is the influence of short circuit current (Jsc) value change, and thus, photoelectric conversion efficiency change of an organic solar cell using metal oxide film combined with carbon nanotube according to the present invention is low even after 50 days of using the organic solar cell (See FIG. 11 (a),(b)).

### Experimental Example 7

### Photo-Electric Conversion Efficiency Analysis of an Organic Solar Cell Under Ultra-Violet (UV) Light

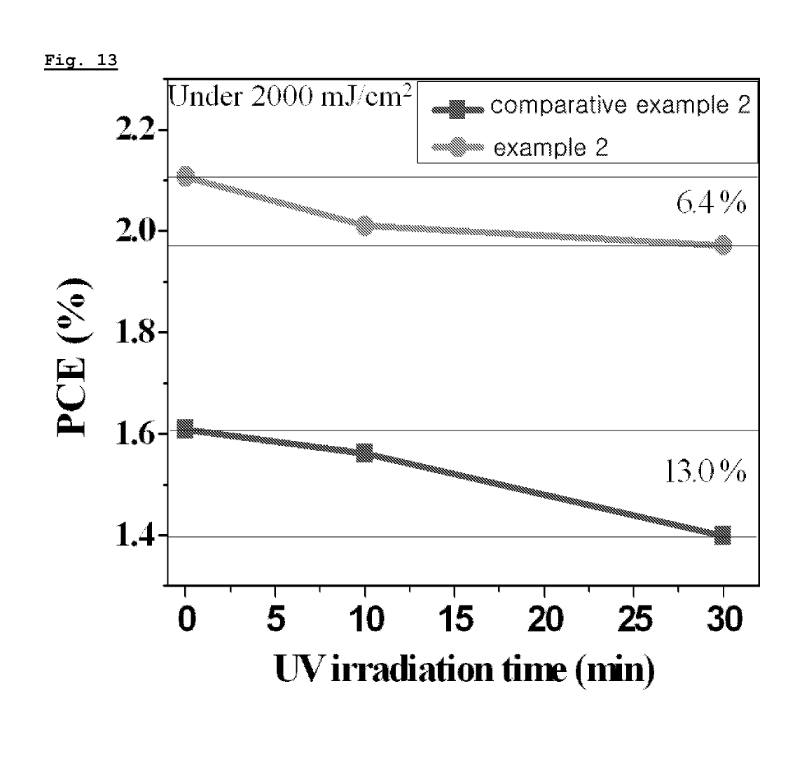

Photoelectric conversion efficiency of an organic solar cell according to the present invention under ultra-violet light was measured and the result is presented in FIG. 13.

2,000 mJ/cm² of UV beam lighter was exposed toward each organic solar cell in order to measure photoelectric conversion efficiency under UV light.

Referring to FIG. 13, it was recognized that photoelectric conversion efficiency of an organic solar cell of Example 2 according to the present invention slowly deteriorated approximately twice the photoelectric conversion efficiency of a conventional OPV.

### Experimental Example 8

### Surface Analysis (II) of Carbon Nanotube-Invaded Metal Oxide Composite Film

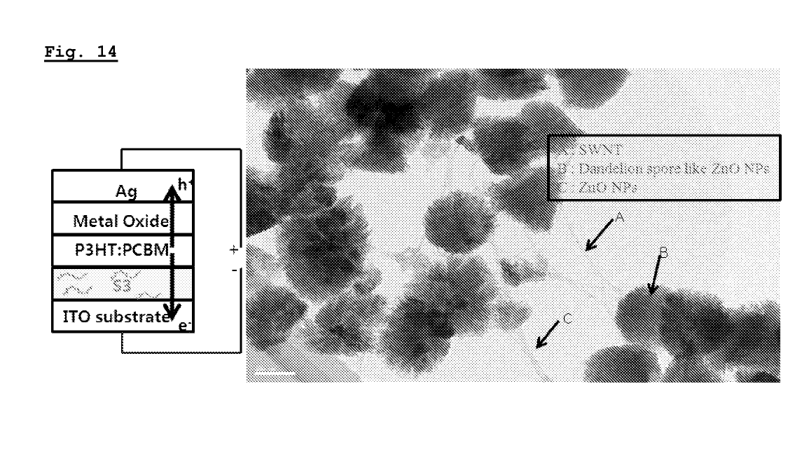

TEM (JEOL 2010) analysis was performed regarding the surface of carbon nanotube-invaded metal oxide composite film according to the present invention, and the result is presented in FIG. 14.

Referring to FIG. 14, it was recognized that the carbon nanotube-invaded metal oxide composite film used in Example 3 had quite rough surface since ZnO was created in various sizes (i.e., 10-200 nm) when the ZnO surface treated carbon nanotube was manufactured, in which ZnO was formed in dandelion spore shape.

Accordingly, it was confirmed that although the surface of the composite film became rougher, short circuit current value was increased as demonstrated in Experimental Example 3 and photoelectric conversion efficiency of an organic solar cell was improved by invasion of carbon nanotube.

1. A carbon nanotube-invaded metal oxide composite film comprising a single-wall carbon nanotube uniformly dispersed in metal oxide.

2. The carbon nanotube-invaded metal oxide composite film according to claim 1 which is any one selected from a group consisting of:
one type of N-type metal oxide which is one selected from a group consisting of TiO₂, ZnO and SnO;
a compound of two or more of the above; and
the metal oxide doped with one or more kinds of atoms selected from a group consisting of Al, Ga, Ng, In and Sn.

3. The carbon nanotube-invaded metal oxide composite film according to claim 1, wherein thickness of the carbon nanotube-invaded metal oxide composite film is in a range between 10 and 100 nm.

4. A method of manufacturing the carbon nanotube-invaded metal oxide composite film of claim 1, the method comprising:
preparing metal oxide sol-gel solution by sequentially dissolving metal oxide and stabilizer in ethanolic solution (step 1);
adding and dispersing single-wall carbon nanotube in the metal oxide sol-gel solution prepared in step 1 to treat surface of single-wall carbon nanotube, and then performing centrifugation (step 2);
adding and re-dispersing the surface treated single-wall carbon nanotube of step 2 in the metal oxide sol-gel solution prepared in step 1 (step 3); and
coating transparent conductive electrode with the metal oxide sol-gel solution with dispersed single-wall carbon nanotube therein of step 3 and performing heat treatment (step 4).

5. The method according to claim 4, the metal oxide of step 1 is any one selected from a group consisting of:
one type of metal oxide selected from a group consisting of TiO₂, ZnO and SnO;
a compound of two or more of the above; and
the metal oxide doped with one or more kinds of atoms selected from a group consisting of Al, Ga, Ng, In and Sn.

6. The method according to claim 4, wherein the single-wall carbon nanotube of step 2 is added to metal oxide sol-gel solution in an amount of 0.1-5 weight %.

7. The method according to claim 4, wherein the coating of step 4 comprises depositing by spin coating, spray coating or doctor blading.

8. An organic solar cell improved photoelectric conversion efficiency and durability, wherein the organic solar cell comprises the carbon nanotube-invaded metal oxide composite film of claim 1.

9. The organic solar cell according to claim 8, wherein the organic solar cell is laminated in the order of substrate/transparent conductive electrode/N-type metal oxide conductive film/photoactive layer/P-type metal oxide conductive film/metal electrode, and the N-type metal oxide conductive film thereof is carbon nanotube-invaded metal oxide composite film of claim 1.
